(19) United States
(12) Patent Application Publication
(10) Pub. No.: US 2019/0104641 A1
(43) Pub. Date: Apr. 4, 2019

(54) ELECTRONIC DEVICE WITH LIQUID COOLING FUNCTION AND LIQUID-COOLING HEAT DISSIPATION MODULE AND LIQUID-COOLING RADIATOR THEREOF

(71) Applicant: AURAS Technology Co., Ltd., New Taipei City (TW)

(72) Inventors: MU-SHU FAN, New Taipei City (TW); CHE-CHIA CHANG, New Taipei City (TW); YU-TING CHANG, New Taipei City (TW)

(21) Appl. No.: 16/144,131

(22) Filed: Sep. 27, 2018

Related U.S. Application Data
(60) Provisional application No. 62/565,516, filed on Sep. 29, 2017.

(51) Int. Cl. H05K 7/20

(52) U.S. Cl. CPC H05K 7/20263; H05K 7/2039; H05K 7/20272

(57) ABSTRACT

An electronic device with a liquid cooling function, a liquid-cooling heat dissipation module and a liquid-cooling radiator are provided. The liquid-cooling radiator includes a first reservoir, a second reservoir, a third reservoir, a first heat-dissipation channel group and a second heat-dissipation channel group. The first reservoir is arranged between the second reservoir and the third reservoir. The first heat-dissipation channel group is arranged between the first reservoir and the second reservoir. The second heat-dissipation channel group is arranged between the first reservoir and the third reservoir. An accommodation space is located at a corner of the liquid-cooling radiator and aligned with a radiator outlet. An included angle is formed between an orientation direction of the radiator outlet and an orientation direction of a radiator inlet along a projection surface.

### CROSS-REFERENCE TO RELATED APPLICATION

This application claims priority to U.S. Provisional Patent Application No. 62/565,516 filed Sep. 29, 2017, the contents of which are incorporated herein by reference.

### FIELD OF THE INVENTION

The present invention relates to an electronic device with a liquid cooling function, a liquid-cooling heat dissipation module and a liquid-cooling radiator, and more particularly to an electronic device for a computer system, a liquid-cooling heat dissipation module and a liquid-cooling radiator so as to reduce the occupied space and increase the heat dissipation efficiency.

### BACKGROUND OF THE INVENTION

With increasing development of science and technology, various electronic devices (or computers) such as notebook computers, desktop computers or network servers have become indispensable devices in the daily lives of people. Generally, during the operation of the electronic device, the temperature of the electronic components of the electronic device gradually increases. The elevated temperature may result in damage of the electronic components. For solving these problems, the electronic device is usually equipped with a heat dissipating mechanism. In accordance with a conventional heat dissipating mechanism, a fan is used to produce airflow to cool the electronic component through convection, or a heat dissipating unit made of a special material is attached on the electronic component to reduce the temperature through thermal conduction. In addition, a liquid-cooling mechanism is one of the effective and common heat dissipating mechanisms.

The operating principles of the liquid-cooling mechanism will be described as follows. Generally, the liquid-cooling mechanism uses liquid (e.g., water or coolant) as the cooling medium, and uses a continuously-running pump to move the liquid within an applied system along a circulating loop. The liquid flows along sealed pipes. The pipes are distributed to the surfaces of the electronic components (e.g., the central processing unit). When the liquid with the lower temperature flows through the electronic component with the higher temperature, the liquid absorbs the heat from the electronic component to decrease the temperature of the electronic component. Then, through heat exchange, the heat is released from the pipes to the surroundings or another heat dissipating mechanism. Consequently, the temperature of the liquid is decreased. Then, the liquid flows back to the system and flows along the circulating loop to remove the heat.

Nowadays, in the image displaying technology, the display cards or the display processing chips (e.g., especially the display card and the display processing chip in the host of the desktop computer) have strong computing and image processing capabilities. Consequently, the imaging quality is gradually increased. During the operations, these products generate a great deal of heat and thus the temperature increases. For decreasing the temperature, these products are usually equipped with standalone heat dissipation modules (e.g., air-cooling mechanisms and liquid-cooling mechanisms). Consequently, the displayed images are not abnormal or the associated components are not damaged.

However, since the inner space of the general host is limited, it is necessary to make full use of the installation environment of the heat dissipation modules. Moreover, the input structures and the output structures of the pipes of the liquid-cooling heat dissipation module have certain thickness or volume. In other words, it is difficult to design the kind of heat dissipation module.

Therefore, there is a need of designing a liquid-cooling heat dissipation module with enhanced heat-dissipating efficacy. The liquid-cooling heat dissipation module can effectively allocate the piping system and reduce the occupied space of the piping system. Consequently, the liquid-cooling heat dissipation module is suitably installed in a narrow environment.

### SUMMARY OF THE INVENTION

An object of the present invention provides an electronic device with a liquid cooling function, a liquid-cooling heat dissipation module and a liquid-cooling radiator. The liquid-cooling heat dissipation module can effectively allocate the piping system and reduce the occupied space of the piping system. Consequently, the liquid-cooling heat dissipation module is suitably applied to and installed in the computer system. Since the airflow generated by the fan is effectively utilized by the liquid-cooling radiator, the heat dissipating efficacy is further enhanced.

In accordance with an aspect of the present invention, there is provided a liquid-cooling radiator. The liquid-cooling radiator includes a first reservoir, a second reservoir, a third reservoir, a first heat-dissipation channel group and a second heat-dissipation channel group. The first reservoir includes a radiator inlet and a radiator outlet. The first reservoir has a first height. The second reservoir has a second height. The second height is smaller than the first height. The first reservoir is arranged between the second reservoir and the third reservoir. The first heat-dissipation channel group is arranged between the first reservoir and the second reservoir. The first heat-dissipation channel group has a first width. The second heat-dissipation channel group is arranged between the first reservoir and the third reservoir. The second heat-dissipation channel group has a second width. The second width is larger than the first width. The first reservoir, the second reservoir, the third reservoir, the first heat-dissipation channel group and the second heat-dissipation channel group are in fluid communication with each other.

In accordance with another aspect of the present invention, there is provided a liquid-cooling heat dissipation module. The liquid-cooling heat dissipation module includes a liquid-cooling radiator, a pump and a liquid-cooling head. The liquid-cooling radiator includes a radiator inlet and a radiator outlet. An accommodation space is located at a corner of the liquid-cooling radiator. The accommodation space is aligned with the radiator outlet. The pump is in fluid communication with the radiator outlet for circularly transferring a liquid. The liquid-cooling head has a head inlet and a head outlet. The head inlet is in fluid communication with the pump. The head outlet is connected with the radiator inlet. Moreover, there is an included angle between an orientation direction of the radiator outlet and an orientation direction of the radiator inlet along a projection surface.

In accordance with a further aspect of the present invention, there is provided an electronic device with a liquid cooling function. The electronic device is applied to a computer system. The electronic device includes a circuit board, a liquid-cooling radiator, a pump, a liquid-cooling head and a fan group. The circuit board has a processing unit. The liquid-cooling radiator includes a radiator inlet and a radiator outlet. An accommodation space is located at a corner of the liquid-cooling radiator. The accommodation space is aligned with the radiator outlet. The pump is in fluid communication with the radiator outlet for circularly transferring a liquid. The liquid-cooling head is aligned and contacted with the processing unit, and has a head inlet and a head outlet. The head inlet is in fluid communication with the pump. The head outlet is connected with the radiator inlet. The fan group is installed on the liquid-cooling radiator. The fan group and the liquid-cooling head are opposed to each other with respect to the liquid-cooling radiator. Moreover, there is an included angle between an orientation direction of the radiator outlet and an orientation direction of the radiator inlet along a projection surface.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a schematic perspective view illustrating a liquid-cooling heat dissipation module according to a first embodiment of the present invention;

FIG. 1B is a schematic perspective view illustrating the liquid-cooling heat dissipation module as shown in FIG. 1A and taken along another viewpoint;

FIG. 2A is a schematic exploded view illustrating the liquid-cooling heat dissipation module as shown in FIG. 1A;

FIG. 2B is a schematic front view illustrating a liquid-cooling radiator of the liquid-cooling heat dissipation module as shown in FIG. 1A;

FIG. 3A is a schematic perspective view illustrating a portion of the liquid-cooling heat dissipation module as shown in FIG. 1A;

FIG. 3B is a schematic perspective view illustrating the liquid-cooling head of the liquid-cooling heat dissipation module according to the first embodiment of the present invention and taken along another viewpoint;

FIG. 3C is a schematic cutaway view illustrating the liquid-cooling radiator of the liquid-cooling heat dissipation module according to the first embodiment of the present invention;

FIG. 4A is a schematic perspective view illustrating a liquid-cooling heat dissipation module according to a second embodiment of the present invention;

FIG. 4B is a schematic perspective view illustrating the liquid-cooling heat dissipation module as shown in FIG. 4A and taken along another viewpoint; and

FIG. 5 is a schematic top view illustrating an electronic device with a liquid cooling function according to a third embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

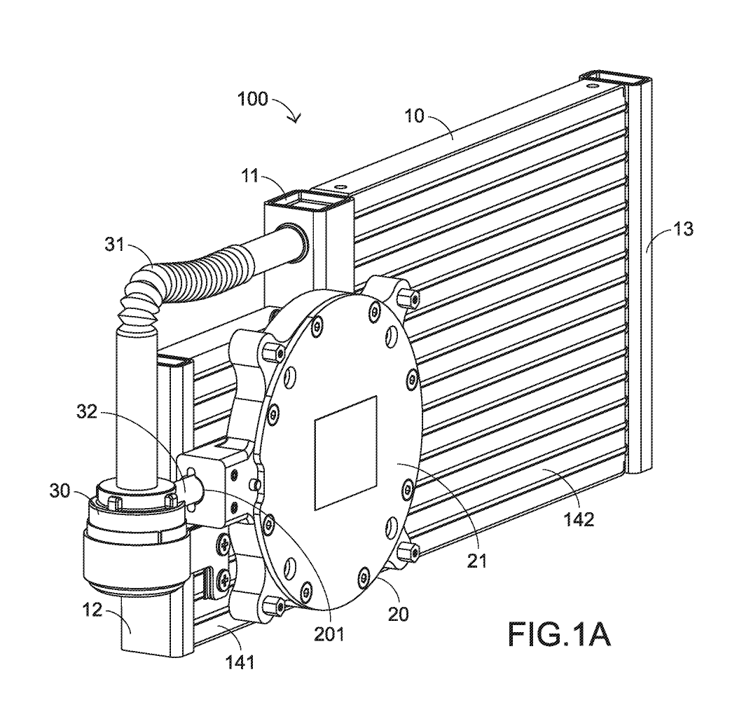

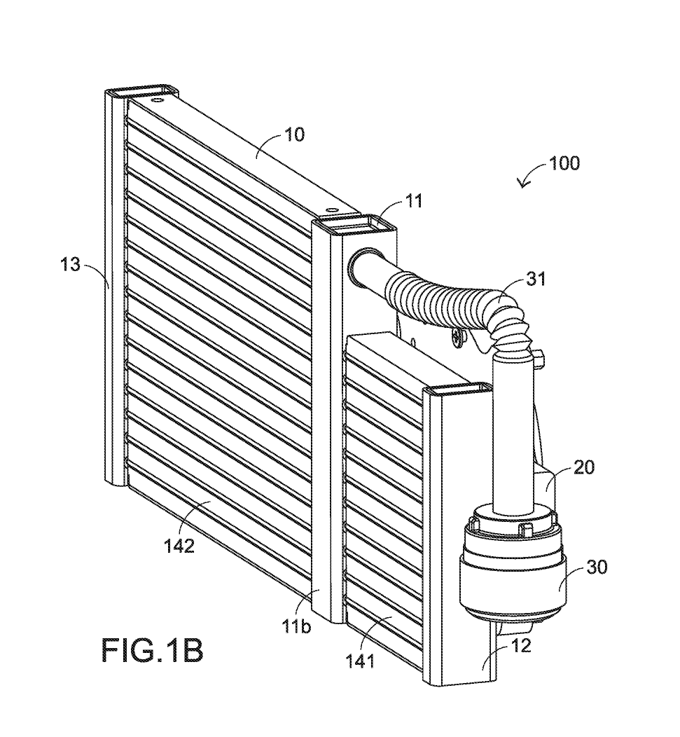

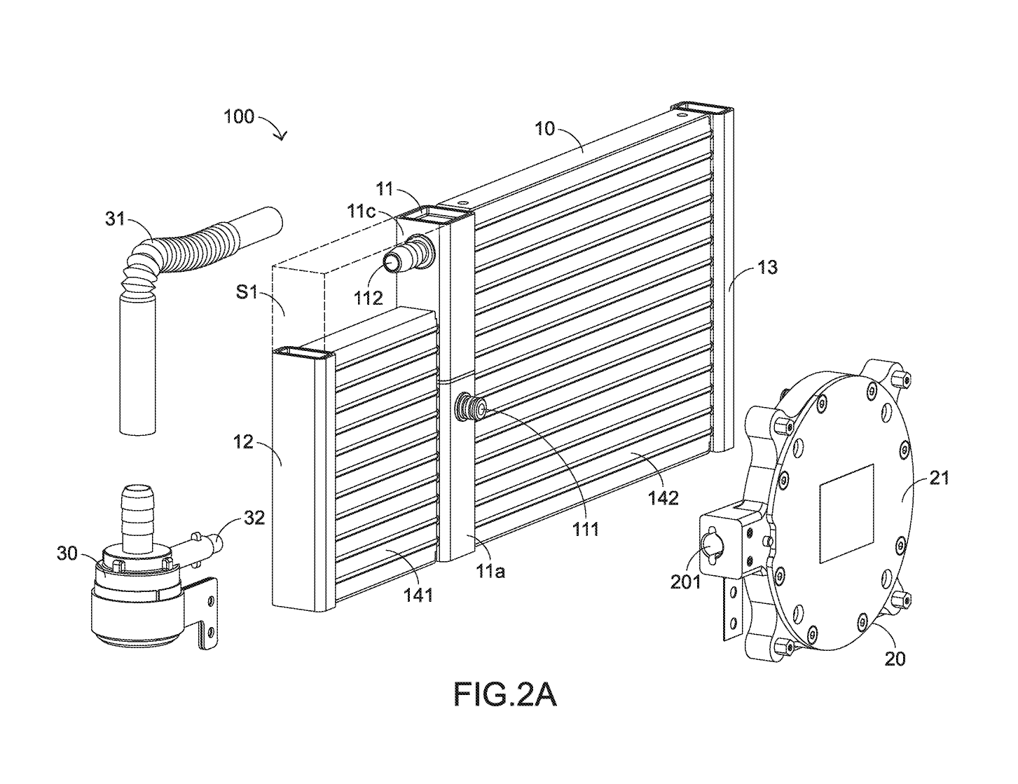

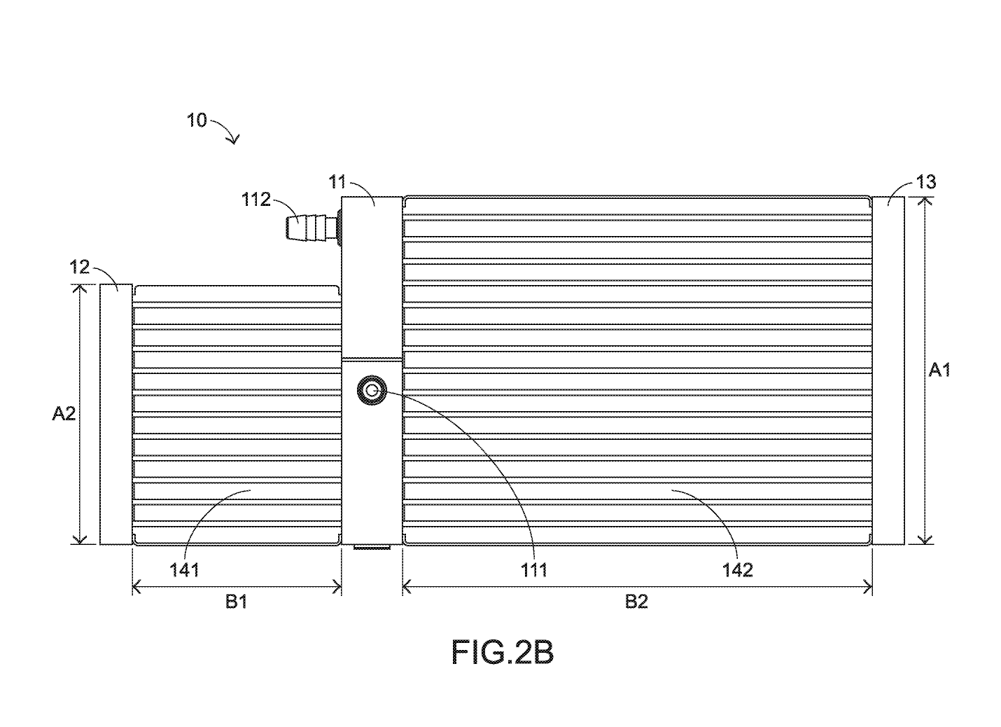

A liquid-cooling heat dissipation module according to a first embodiment of the present invention will be described as follows. Please refer to FIGS. 1A, 1B, 2A and 2B. FIG. 1A is a schematic perspective view illustrating a liquid-cooling heat dissipation module according to a first embodiment of the present invention. FIG. 1B is a schematic perspective view illustrating the liquid-cooling heat dissipation module as shown in FIG. 1A and taken along another viewpoint. FIG. 2A is a schematic exploded view illustrating the liquid-cooling heat dissipation module as shown in FIG. 1A. FIG. 2B is a schematic front view illustrating a liquid-cooling radiator of the liquid-cooling heat dissipation module as shown in FIG. 1A.

As shown in FIGS. 1A, 1B, 2A and 2B, the liquid-cooling heat dissipation module 100 comprises a liquid-cooling radiator 10, a liquid-cooling head 20 and a pump 30.

The liquid-cooling radiator 10 comprises a first reservoir 11, a second reservoir 12, a third reservoir 13, a first heat-dissipation channel group 141 and a second heat-dissipation channel group 142. The first reservoir 11 is arranged between the second reservoir 12 and the third reservoir 13. The first heat-dissipation channel group 141 is arranged between the first reservoir 11 and the second reservoir 12. The second heat-dissipation channel group 142 is arranged between the first reservoir 11 and the third reservoir 13. The first reservoir 11, the second reservoir 12, the third reservoir 13, the first heat-dissipation channel group 141 and the second heat-dissipation channel group 142 are in fluid communication with each other.

In accordance with a feature of the present invention, the size of the first heat-dissipation channel group 141 and the size of the second heat-dissipation channel group 142 are different. As shown in FIG. 2B, the first reservoir 11 has a first height A1, the third reservoir 13 also has the first height A1, and the second reservoir 12 has a second height A2. The second height A2 is smaller than the first height A1. The first heat-dissipation channel group 141 has a first width B1. The height of the first heat-dissipation channel group 141 is close to the height of the second reservoir 12. The second heat-dissipation channel group 142 has a second width B2, which is larger than the first width B1. The height of the second heat-dissipation channel group 142 is close to the height of the first reservoir 11 (and the third reservoir 13). In other words, the area of the first heat-dissipation channel group 141 is smaller than the area of the second heat-dissipation channel group 142.

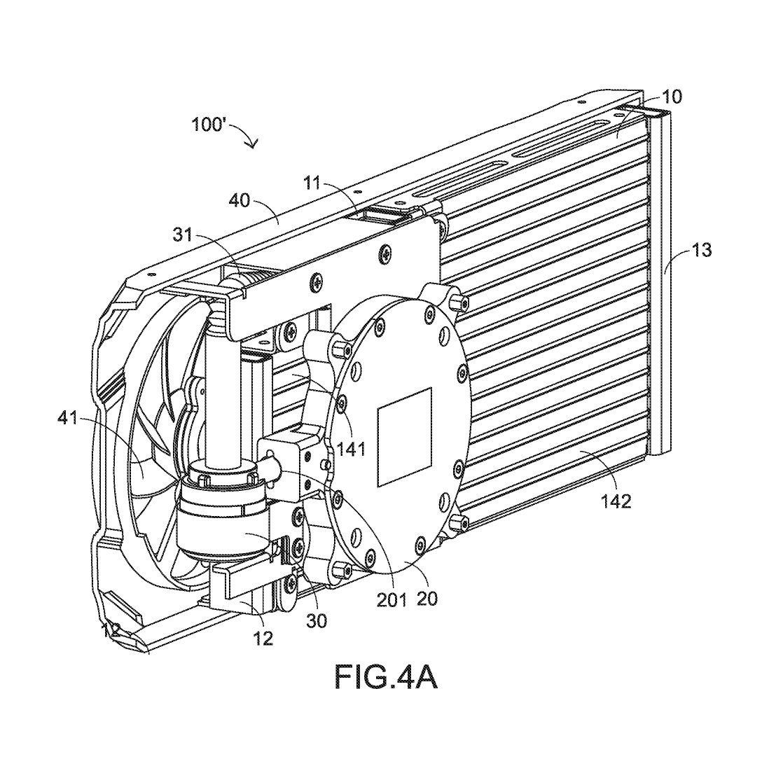

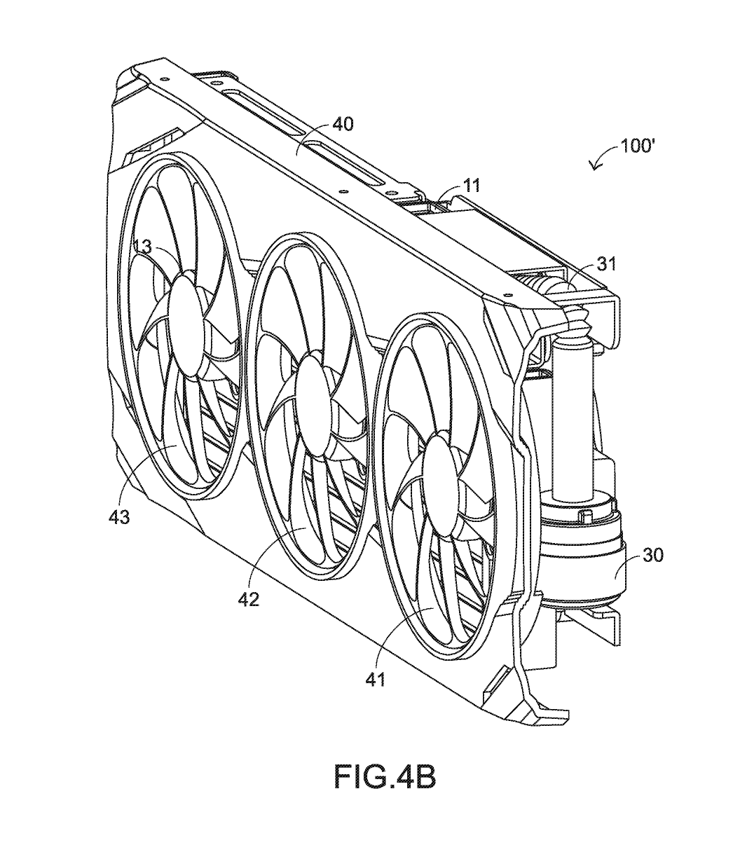

Furthermore, the liquid-cooling heat dissipation module 100 further comprises a fan group (see FIGS. 4A and 4B). The first reservoir 11 has a first lateral side 11a and a second lateral side 11b, which are opposed to each other. The liquid-cooling head 20 is installed on the first lateral side 11a. The fan group is installed on the second lateral side 11b. The fan group comprises plural fans. The structures of the fans are similar to the conventional fans. Preferably but not exclusively, the plural fans are arranged in a line. As mentioned above, the heat-dissipation channel groups have different sizes. Consequently, the sizes, shapes and distribution ranges of the heat-dissipation channel groups may be specially designed to match the corresponding fans. Consequently, when compared with the conventional technologies, the heat dissipating efficiency of the liquid-cooling heat dissipation module of the present invention is enhanced. The detailed examples will be described as follows.

In accordance with another feature of the present invention, an accommodation space 51 is located at a corner of the overall liquid-cooling radiator 10. Please refer to FIGS. 1A, 1B, 2A and 2B again. The first reservoir 11 has a radiator inlet 111 and a radiator outlet 112. The radiator inlet 111 is connected with the liquid-cooling head 20. The radiator outlet 112 is in fluid communication with the pump 30. The pump 30 is also in fluid communication with the liquid-cooling head 20. The pump 30 is used for transferring a liquid. The pump 30 is arranged beside the second reservoir 12. In this embodiment, the radiator outlet 112 is connected with the pump 30 through an input pipe 31, and the liquid-cooling head 20 is connected with the pump 30 through an output pipe 32. Consequently, the above components are in fluid communication with each other, and the cooling liquid is transferred circularly.

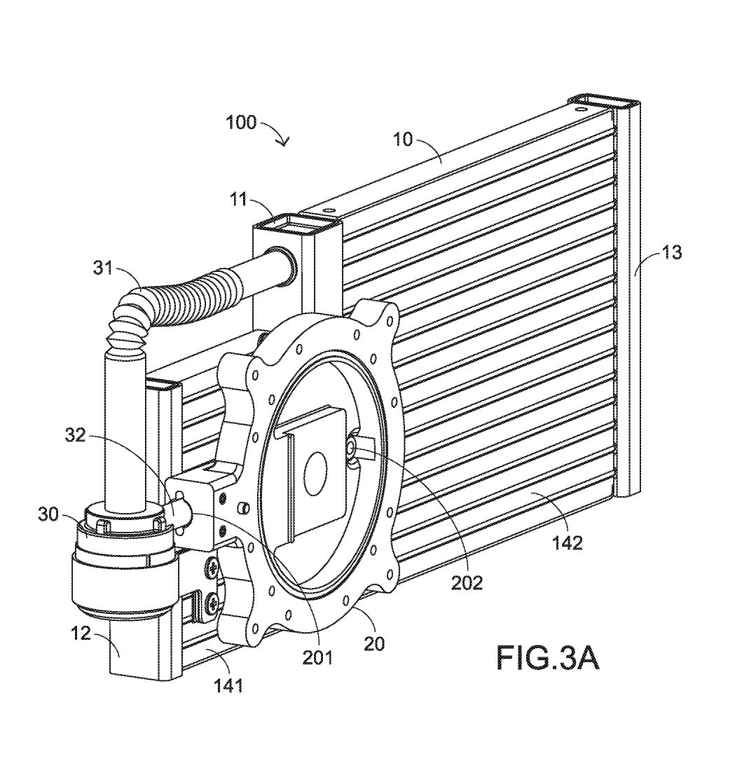

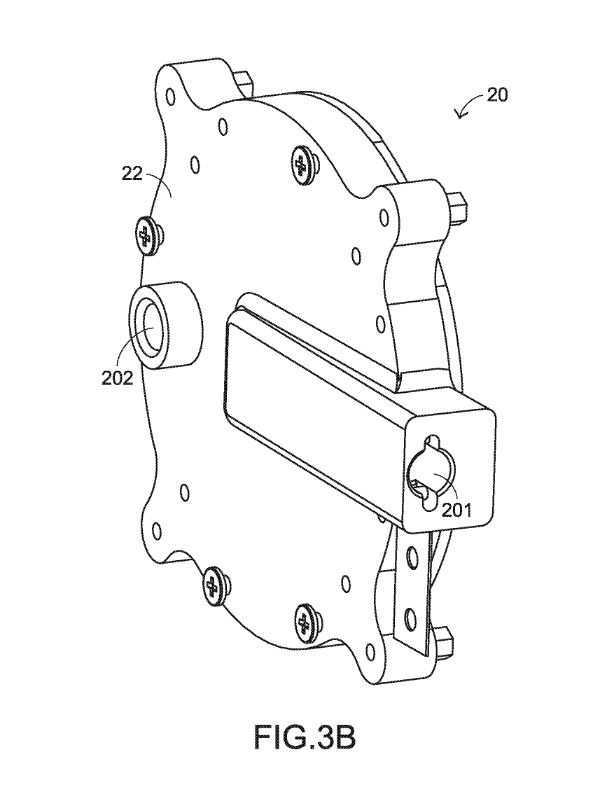

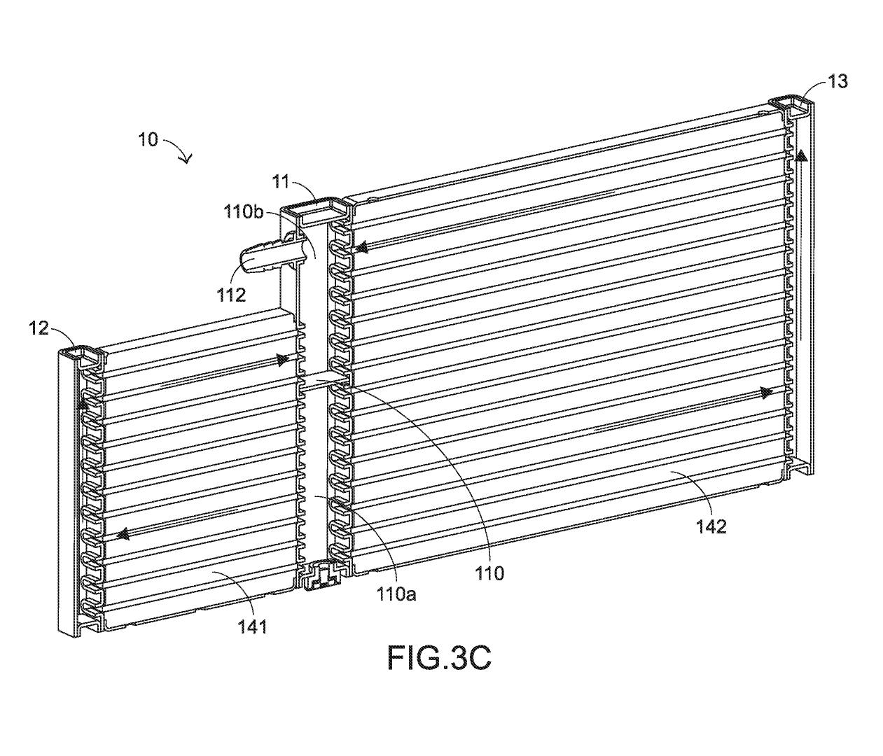

Moreover, the liquid-cooling head 20 and the liquid-cooling radiator 10 are connected with each other in a pipe-to-pipe coupling manner (see also FIGS. 3A and 3B). Consequently, the junction between the liquid-cooling head 20 and the liquid-cooling radiator 10 does not occupy much space. Moreover, the accommodation space 51 is located over the first heat-dissipation channel group 141. That is, when the first reservoir 11 and the first heat-dissipation channel group 141 are combined together, a notch is defined between the first reservoir 11 and the first heat-dissipation channel group 141 and the notch is formed as the accommodation space 51. Since the first heat-dissipation channel group 141 or the second reservoir 12 is at a level lower than the first reservoir 11, the accommodation space or the notch is correspondingly formed.

The radiator outlet 112 is located at a top side 11c of the first reservoir 11. In other words, the accommodation space 51 is aligned with the radiator outlet 112. Consequently, the pump 30 and the radiator outlet 112 are connected with each other through the input pipe 31 that is partially accommodated within the accommodation space 51.

When compared with the conventional technology, the occupied space of the input pipe 31 in the liquid-cooling heat dissipation module is reduced and the number of the crooked or bent regions of the input pipe 31 is reduced. Consequently, the flowing condition of the liquid is not blocked, or the liquid is not leaked out through the high pressure site.

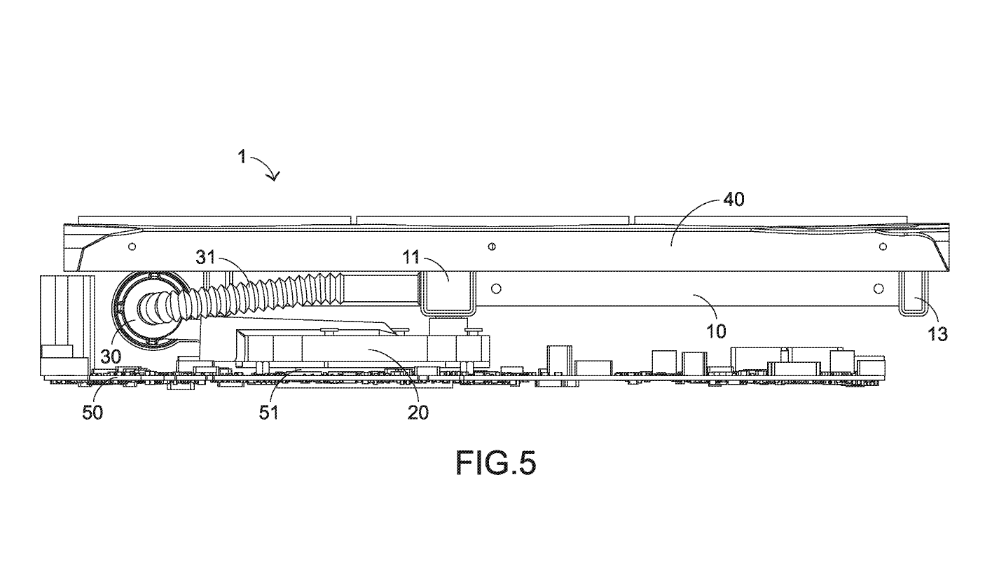

The radiator inlet 111 is located at the first lateral side 11a. Consequently, there is an included angle between an orientation direction of the radiator outlet 112 and an orientation direction of the radiator inlet 111 along a projection surface. The projection surface is taken from a top view (e.g., the drawing of FIG. 5). For example, the included angle is 90 degrees. Preferably, the included angle is not larger than 90 degrees. In this embodiment, the radiator inlet 111 is at a level lower than the radiator outlet 112. The radiator inlet 111 is directly coupled to a head outlet 202 of the liquid-cooling head 20 (see FIG. 3B). Moreover, the orientation direction of a head inlet 201 of the liquid-cooling head 20 is approximately perpendicular to the orientation direction of the head outlet 202. Consequently, the orientation direction of the radiator outlet 112 and the orientation direction of the head inlet 201 are nearly parallel with each other.

When compared with the conventional technology, the input pipe 31 and the output pipe 32 are very close to the first heat-dissipation channel group 141. Consequently, the complexity of the piping system is reduced. Moreover, the width of the first heat-dissipation channel group 141 is close to the width of the liquid-cooling head 20. That is, the width of the first heat-dissipation channel group 141 is smaller. Consequently, even if the output pipe 32 is not long enough, the output pipe 32 can be connected with the head inlet 201. In case that the sizes of the associated components are properly designed, the pump 30 can be directly with the head inlet 201 without the need of using pipes. When compared with the conventional technology, the structures for resulting in the fluid communication between the liquid-cooling radiator 10, the pump 30 and the liquid-cooling head 20 and the structures for transferring the liquid can reduce the thickness of the overall module.

Please refer to FIGS. 3A, 3B and 3C. FIG. 3A is a schematic perspective view illustrating a portion of the liquid-cooling heat dissipation module as shown in FIG. 1A. FIG. 3B is a schematic perspective view illustrating the liquid-cooling head of the liquid-cooling heat dissipation module according to the first embodiment of the present invention and taken along another viewpoint. FIG. 3C is a schematic cutaway view illustrating the liquid-cooling radiator of the liquid-cooling heat dissipation module according to the first embodiment of the present invention.

After a bottom surface 21 of the liquid-cooling head 20 as shown in FIG. 1A is removed, the resulting structure of the liquid-cooling heat dissipation module is shown in FIG. 3A. As shown in FIG. 3A, the liquid is introduced into the inner portion of the liquid-cooling head 20 through the head inlet 201. The inner portion of the liquid-cooling head 20 is a single chamber. As shown in FIGS. 2A, 3A and 3B, the head outlet 202 is formed in a top surface 22 of the liquid-cooling head 20 and aligned with the radiator inlet 111. As mentioned above, the liquid passing through the liquid-cooling radiator 10 is cooled down. That is, the temperature of the liquid flowing into the head inlet 201 is lower. After the liquid flows through the liquid-cooling head 20, the heat from the component (e.g., the processing unit or the display processing chip) in contact with the bottom surface 21 is absorbed by the liquid. Then, the heat is dissipated away from the head outlet 202.

Please refer to FIGS. 2A and 3C. The first reservoir 11 is divided into an upper chamber 110b and a lower chamber 110a by a partition plate 110. The radiator inlet 111 and the head outlet 202 are aligned with the lower chamber 110a. The radiator outlet 112 is aligned with the upper chamber 110b. In FIG. 3C, the flowing direction of the liquid is indicated by arrows. Each of the first heat-dissipation channel group 141 and the second heat-dissipation channel group 142 comprises plural flow channels. The two ends of each flow channel are open ends. In addition, the plural flow channels are separated from each other.

After the liquid with a higher temperature is introduced into the lower chamber 110a through the radiator inlet 111, the liquid is transferred to the flow channels corresponding to the half-lower portion of the first heat-dissipation channel group 141 or the second heat-dissipation channel group 142. Then, the liquid is transferred to the second reservoir 12 or the third reservoir 13. Then, the liquid is compressed, and thus the liquid within the second reservoir 12 or the third reservoir 13 flows up. Then, the liquid is transferred to the middle region through the half-upper portion of the first heat-dissipation channel group 141 or the second heat-dissipation channel group 142. Then, the liquid is collected in the upper chamber 110b and outputted from the radiator outlet 112.

In this embodiment, the radiator inlet 111 and the radiator outlet 112 are nozzles that are protruded to the outside and have smaller diameters. The head outlet 202 and the input pipe 31 with the larger diameters are docked with the radiator inlet 111 and the radiator outlet 112, respectively. For increasing the connecting tightness, two leak-proof rings are sheathed around the peripheries of the radiator inlet 111 and the radiator outlet 112, respectively. Consequently, the liquid is not leaked out to the surroundings through the seams. The sizes, shapes or docking ways of the pipe openings or pipes are presented herein for purpose of illustration and description only.

A liquid-cooling heat dissipation module according to a second embodiment of the present invention will be described as follows. Please refer to FIGS. 4A and 4B. FIG. 4A is a schematic perspective view illustrating a liquid-cooling heat dissipation module according to a second embodiment of the present invention. FIG. 4B is a schematic perspective view illustrating the liquid-cooling heat dissipation module as shown in FIG. 4A and taken along another viewpoint.

In comparison with the first embodiment, the liquid-cooling heat dissipation module 100′ of the second embodiment further comprises a fan group 40. The fan group 40 is a part of the liquid-cooling heat dissipation module 100′. In this embodiment, the fan group 40 comprises three fans 41, 42 and 43. It is noted that the number of the fans is not restricted. For example, in another embodiment, the fan group 40 comprises one fan, two fans or more than three fans. The fan group 40 is installed on the second lateral side 11b of the first reservoir 11 that is opposed to the first lateral side 11a. That is, the fan group 40 and the liquid-cooling head 20 are opposed to each other with respect to the liquid-cooling radiator 10, and the fan group 40 is aligned with the first heat-dissipation channel group 141 or the second heat-dissipation channel group 142.

As mentioned in the first embodiment, the airflow generated by the fan group 40 removes the heat from the liquid when the liquid flows through the first heat-dissipation channel group 141 or the second heat-dissipation channel group 142 back or forth. Consequently, the liquid is cooled down. The first heat-dissipation channel group 141 and the second heat-dissipation channel group 142 have different sizes. For example, the area of the second heat-dissipation channel group 142 is twice the size of the first heat-dissipation channel group 141. Moreover, the two fans 42 and 43 match the second heat-dissipation channel group 142, and the fan 41 matches the first heat-dissipation channel group 141. Since the airflow generated by the three fans 41, 42 and 43 is guided to the surfaces of the flow channels, the heat dissipating efficacy is optimized.

The present invention further provides an electronic device with a liquid cooling function. FIG. 5 is a schematic top view illustrating an electronic device with a liquid cooling function according to a third embodiment of the present invention.

In comparison with the second embodiment, the electronic device 1 comprises the liquid-cooling heat dissipation module of the second embodiment and a circuit board 50. As shown in FIG. 5, the circuit board 50 is located beside the liquid-cooling head 20. Consequently, a processing unit 51 of the circuit board 50 is aligned and contacted with the liquid-cooling head 20. For succinctness and clarification, the brackets for assembling the above components are not shown in FIG. 5. Consequently, the relative locations between the fan module 40, the liquid-cooling head 20, the liquid-cooling radiator 10, the pump 30 and the circuit board 50 can be clearly shown.

The electronic device 1 is applied to a computer system (not shown). For example, the computer system is a personal computer or a desktop computer. In an embodiment, the circuit board 50 is a display card, and the processing unit 51 of the circuit board 50 is a display processing chip. The liquid-cooling heat dissipation module that is optionally equipped with the fan module) is designed according to the size the applied circuit board 50. Consequently, even if the circuit board 50 and the liquid-cooling heat dissipation module are fabricated by different production line or different production units, the circuit board 50 and the liquid-cooling heat dissipation module can be well assembled in the subsequent process.

The circuit board 50 comprises a substrate, a transmission interface and any other appropriate basic component. In other words, the circuit board 50 takes a certain space of the computer system (especially the host). As mentioned in the first embodiment and the second embodiment, the overall thickness of the liquid-cooling heat dissipation module and the fan module is reduced when compared with the conventional liquid-cooling heat dissipation module. In accordance with the present invention, the inherent space of the circuit board 50 in the computer system is used to accommodate the liquid-cooling heat dissipation module. Consequently, the electronic device 1 occupies less space while achieving satisfied heat dissipating efficacy.

From the above descriptions, the present invention provides an electronic device with a liquid cooling function, a liquid-cooling heat dissipation module and a liquid-cooling radiator. When compared with the conventional technologies, the technologies of the present invention are capable of enhancing the space utilization of the liquid-cooling device or the heat dissipating efficiency. The liquid-cooling heat dissipation module of the present invention can effectively allocate the piping system and reduce the occupied space of the piping system. Consequently, the liquid-cooling heat dissipation module is suitably applied to and installed in the computer system. Moreover, since the airflow generated by the fan is effectively utilized by the liquid-cooling radiator, the heat dissipating efficacy is further enhanced. In other words, the technologies of the present invention can effectively solve the drawbacks of the conventional technology while achieving the purposes of the present invention.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A liquid-cooling radiator, comprising:
a first reservoir comprising a radiator inlet and a radiator outlet, wherein the first reservoir has a first height;
a second reservoir having a second height, wherein the second height is smaller than the first height;
a third reservoir, wherein the first reservoir is arranged between the second reservoir and the third reservoir;
a first heat-dissipation channel group arranged between the first reservoir and the second reservoir, wherein the first heat-dissipation channel group has a first width; and
a second heat-dissipation channel group arranged between the first reservoir and the third reservoir, wherein the second heat-dissipation channel group has a second width, and the second width is larger than the first width,
wherein the first reservoir, the second reservoir, the third reservoir, the first heat-dissipation channel group and the second heat-dissipation channel group are in fluid communication with each other.

2. The liquid-cooling radiator according to claim 1, wherein the radiator inlet is connected with a liquid-cooling head, the radiator outlet is in fluid communication with a pump, and the pump is in fluid communication with the liquid-cooling head so as to circularly transfer a liquid.

3. The liquid-cooling radiator according to claim 1, wherein the radiator inlet is connected with a liquid-cooling head, the liquid-cooling radiator is installed on a circuit board, the circuit board has a processing unit, and the liquid-cooling head is aligned and contacted with the processing unit.

4. The liquid-cooling radiator according to claim 1, wherein when the first reservoir and the first heat-dissipation channel group are combined together, a notch is defined between the first reservoir and the first heat-dissipation channel group and the notch is formed as an accommodation space, wherein the accommodation space is aligned with the radiator outlet, and the radiator outlet is connected with a pump through an input pipe that is partially accommodated within the accommodation space.

5. The liquid-cooling radiator according to claim 1, wherein the first reservoir has a top side and a first lateral side, wherein the radiator outlet is located at the top side of the first reservoir, the radiator inlet is located at the first lateral side of the first reservoir, and there is an included angle between an orientation direction of the radiator outlet and an orientation direction of the radiator inlet along a projection surface.

6. The liquid-cooling radiator according to claim 5, wherein the first heat-dissipation channel group and the second heat-dissipation channel group cooperate with a fan group, and the fan group comprises at least one fan, wherein the fan group is located at a second lateral side of the first reservoir which is opposed to the first lateral side of the first reservoir, and the fan group is aligned with the first heat-dissipation channel group and the second heat-dissipation channel group.

7. A liquid-cooling heat dissipation module, comprising:
a liquid-cooling radiator comprising a radiator inlet and a radiator outlet, wherein an accommodation space is located at a corner of the liquid-cooling radiator, and the accommodation space is aligned with the radiator outlet;
a pump in fluid communication with the radiator outlet for circularly transferring a liquid; and
a liquid-cooling head having a head inlet and a head outlet, wherein the head inlet is in fluid communication with the pump, and the head outlet is connected with the radiator inlet,
wherein there is an included angle between an orientation direction of the radiator outlet and an orientation direction of the radiator inlet along a projection surface.

8. The liquid-cooling heat dissipation module according to claim 7, wherein the liquid-cooling heat dissipation module is installed on a circuit board, the circuit board has a processing unit, and the liquid-cooling head is aligned and contacted with the processing unit.

9. The liquid-cooling heat dissipation module according to claim 8, wherein the liquid-cooling head has a top surface and a bottom surface, wherein the head outlet is formed in the top surface of the liquid-cooling head and aligned with the radiator inlet, and the bottom surface of the liquid-cooling head is contacted with the processing unit.

10. The liquid-cooling heat dissipation module according to claim 7, wherein the liquid-cooling radiator comprises:
a first reservoir having a first height;
a second reservoir having a second height, wherein the second height is smaller than the first height;
a third reservoir, wherein the first reservoir is arranged between the second reservoir and the third reservoir;
a first heat-dissipation channel group arranged between the first reservoir and the second reservoir, wherein the first heat-dissipation channel group has a first width; and
a second heat-dissipation channel group arranged between the first reservoir and the third reservoir, wherein the second heat-dissipation channel group has a second width, and the second width is larger than the first width,
wherein the first reservoir, the second reservoir, the third reservoir, the first heat-dissipation channel group and the second heat-dissipation channel group are in fluid communication with each other.

11. The liquid-cooling heat dissipation module according to claim 10, wherein when the first reservoir and the first heat-dissipation channel group are combined together, a notch is defined between the first reservoir and the first heat-dissipation channel group and the notch is formed as an accommodation space, wherein the radiator outlet is connected with the pump through an input pipe that is partially accommodated within the accommodation space.

12. The liquid-cooling heat dissipation module according to claim 10, wherein the first reservoir has a top side and a first lateral side, wherein the radiator outlet is located at the top side of the first reservoir, and the radiator inlet is located at the first lateral side of the first reservoir.

13. The liquid-cooling heat dissipation module according to claim 12, wherein the liquid-cooling heat dissipation module further comprises a fan group, and the fan group comprises at least one fan, wherein the fan group is located at a second lateral side of the first reservoir which is opposed to the first lateral side of the first reservoir, and the fan group is aligned with the first heat-dissipation channel group and the second heat-dissipation channel group.

14. The liquid-cooling heat dissipation module according to claim 7, wherein the liquid-cooling head is connected with the pump through an output pipe.

15. An electronic device with a liquid cooling function, the electronic device being applied to a computer system, the electronic device comprising:
a circuit board having a processing unit;
a liquid-cooling radiator comprising a radiator inlet and a radiator outlet, wherein an accommodation space is located at a corner of the liquid-cooling radiator, and the accommodation space is aligned with the radiator outlet;
a pump in fluid communication with the radiator outlet for circularly transferring a liquid;
a liquid-cooling head aligned and contacted with the processing unit, and having a head inlet and a head outlet, wherein the head inlet is in fluid communication with the pump, and the head outlet is connected with the radiator inlet; and
a fan group installed on the liquid-cooling radiator, wherein the fan group and the liquid-cooling head are opposed to each other with respect to the liquid-cooling radiator,
wherein there is an included angle between an orientation direction of the radiator outlet and an orientation direction of the radiator inlet along a projection surface.
